(19) United States
(12) Patent Application Publication
(10) Pub. No.: US 2014/0159713 A1
(43) Pub. Date: Jun. 12, 2014

(54) HIGH SENSITIVITY MAGNETOELECTRIC MAGNETOMETER

(71) Applicant: Nersesse Nersessian, Jessup, MD (US)

(72) Inventor: Nersesse Nersessian, Jessup, MD (US)

(73) Assignee: MARITIME APPLIED PHYSICS CORPORATION, Baltimore, MD (US)

(21) Appl. No.: 14/093,018

(22) Filed: Nov. 28, 2013

Related U.S. Application Data
(60) Provisional application No. 61/730,746, filed on Nov. 28, 2012.

(51) Int. Cl. G01R 33/02; G01R 33/038

(52) U.S. Cl. CPC G01R 33/02; G01R 33/0385
USPC 324/244

(57) ABSTRACT

Some implementations provide a magnetoelectric magnetometer that includes a piezoelectric layer having a first end portion, a second end portion, and a third portion. The third portion is located between the first end portion and the second end portion. The magnetoelectric magnetometer includes a magnetostrictive element coupled to the third portion of the piezoelectric layer. The magnetostrictive element and the piezoelectric layer are configured to amplify a magnetically induced stress in the magnetostrictive element to the piezoelectric layer, resulting in an electrical response from the piezoelectric layer. The first and second end portions of the piezoelectric layer are fixed, while the third portion is free to bend.

The present application claims priority to U.S. Provisional Application No. 61/730,746 entitled “High Sensitivity Magnetoelectric Magnetometer”, filed Nov. 28, 2012, which is hereby expressly incorporated by reference herein.

### BACKGROUND

1. Field

Various features relate to a high sensitivity magnetoelectric magnetometer.

2. Background

A magnetometer is an instrument used to measure the strength and/or direction of magnetic fields. Magnetometers are used in different applications. Some of these applications include locating objects, such as submarines, sunken ships and hazards in coal mines. Magnetometers are also used in heart rate monitors, weapon systems positioning, and sensors in anti-locking brakes.

There are many different types of magnetometers. One example of a magnetometer is a superconducting quantum interference device (SQUID) magnetometer. One advantage of SQUID magnetometers is that they have high sensitivities relative to other magnetometers. However, to achieve these high sensitivities, SQUID magnetometers must operate at very low temperatures (e.g., near absolute zero). Because SQUID magnetometers cannot achieve these high sensitivities at or near room temperature, they are not practical/useful for day to day applications.

A magnetoelectric magnetometer is another example of a magnetometer. Typically, magnetoelectric magnetometers are composites of magnetostrictive and piezoelectric elements. The magnetostrictive elements convert the magnetic energy to a mechanical energy while the piezoelectric elements convert the mechanical energy to an electrical energy. In such composites, the magnetostrictive and piezoelectric elements are mechanically coupled thereby converting magnetic energy to electrical energy. One downside of magnetoelectric magnetometers is that they are not as sensitive as other magnetometers. Another downside to current magnetoelectric magnetometers is that are not sensitive enough, and they don't have a compact enough form that would be useful for many day to day practical applications. However, the advantage of the magnetoelectric magnetometer is that it can operate at or near room temperature, which makes them ideal for day to day applications.

In view of this, there is a need in the art for a magnetometer that combines some of the best properties of existing magnetometers. Ideally, such a magnetometer will have high sensitivity and can operate at or near room temperature.

### DRAWINGS

Various features, nature and advantages may become apparent from the detailed description set forth below when taken in conjunction with the drawings in which like reference characters identify correspondingly throughout.

FIG. 1 illustrates a view of a magnetoelectric composite having a magnetostrictive element on top a piezoelectric layer.

FIG. 2 illustrates a view of a magnetoelectric composite having a magnetostrictive element below a piezoelectric layer.

FIG. 3 illustrates a view of a magnetoelectric composite having a piezoelectric layer between two magnetostrictive elements.

FIG. 4 illustrates a view of a magnetoelectric composite having a piezoelectric layer, two magnetostrictive elements and a constraint layer.

FIG. 5 illustrates a view of another magnetoelectric composite having a piezoelectric layer, two magnetostrictive elements and a constraint layer.

FIG. 6 conceptually illustrates a flow diagram of a magnetic field being converted into an electrical field.

FIG. 7 illustrates a view of a magnetoelectric composite having a piezoelectric layer with piezoelectric fibers.

FIG. 8 illustrates a conceptual view of two states of a piezoelectric fiber.

FIG. 9 illustrates a conceptual view of the forces involved on a piezoelectric layer when strained and/or stressed.

FIG. 10 illustrates a conceptual view of an angled piezoelectric layer.

FIG. 11 illustrates a view of a magnetoelectric composite having a two piezoelectric layers and two magnetostrictive elements.

FIG. 12 illustrates a view of a magnetoelectric composite having a piezoelectric layer and two magnetostrictive elements.

FIG. 13 illustrates a piezoelectric layer coupled to interdigitated electrodes.

FIG. 14 illustrates a continuous piezoelectric layer in a magnetostrictive magnetometer.

FIG. 15 illustrates a non-continuous piezoelectric layer in a magnetostrictive magnetometer.

FIG. 16 illustrates configurations of two piezoelectric layers with a magnetostrictive element.

FIG. 17 illustrates configurations of piezoelectric elements coupled with a magnetostrictive element.

FIG. 18 illustrates configurations of piezoelectric elements that include metal layers coupled with a magnetostrictive element.

FIG. 19 illustrates configurations of piezoelectric elements that include metal layers coupled with a magnetostrictive element.

FIG. 20 illustrates configurations of piezoelectric elements coupled with a magnetostrictive element.

FIG. 21 illustrates a sequence for providing one or more components of a magnetostrictive magnetometer.

FIG. 22 illustrates other implementations of using stress amplification for a magnetostrictive magnetometer.

### SUMMARY

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Some implementations provide a magnetoelectric magnetometer that includes a piezoelectric layer having a first end portion, a second end portion, and a third portion. The third portion is located between the first end portion and the second end portion. The magnetoelectric magnetometer includes a magnetostrictive element coupled to the third portion of the piezoelectric layer. The magnetostrictive element and the piezoelectric layer are adapted/configured to amplify a magnetically induced stress in the magnetostrictive element to the piezoelectric layer, resulting in an electrical response from the piezoelectric layer. The first and second end portions of the piezoelectric layer are fixed, while the third portion is free to bend.

The magnetoelectric magnetometer further includes a constraint layer coupled to the piezoelectric layer. The constraint layer includes a first constraint end portion and a second constraint end portion. The first constraint end portion is coupled to the first end portion of the piezoelectric layer. The second constraint end portion is coupled to the second end portion of the piezoelectric layer.

The magnetoelectric magnetometer further includes at least one metal layer coupled to the piezoelectric layer. The piezoelectric layer has a first stiffness that is similar to the second stiffness of the magnetostrictive element. The constraint layer has a third stiffness that is substantially higher than the first stiffness.

Some implementations provide a magnetoelectric magnetometer that includes one or more piezoelectric layers and one or more magnetostrictive layers. The magnetostrictive layer and piezoelectric layer are mechanically coupled via a mechanism for amplifying the magnetically induced stress in the magnetostrictive layer by the location of the mechanical coupling and the geometry of the piezoelectric layer.

A first example provides a magnetoelectric magnetometer that includes an electrical active layer comprising a first end portion, a second end portion, and a third portion. The third portion is located between the first end portion and the second end portion. The magnetoelectric magnetometer also includes a magnetostrictive element coupled to the third portion of the electrical active layer. The magnetostrictive element and the electrical active layer are configured to amplify a magnetically induced stress in the magnetostrictive element to the electrical active layer, resulting in an electrical response from the electrical active layer.

In some implementations, the electrical active layer is a piezoelectric layer that exhibits an electrical polarization when subjected to a mechanical stress.

In some implementations, the first and second end portions of the electrical active layer are fixed, while the third portion is free to bend.

In some implementations, the magnetoelectric magnetometer further includes a constraint layer coupled to the electrical active layer. The constraint layer includes a first constraint end portion and a second constraint end portion. The first constraint end portion being coupled to the first end portion of the electrical active layer. The second constraint end portion being coupled to the second end portion of the electrical active layer.

In some implementations, the magnetoelectric magnetometer further includes at least one metal layer coupled to the electrical active layer.

In some implementations, the electrical active layer has a first stiffness that is similar to the second stiffness of the magnetostrictive element. The constraint layer has a third stiffness that is substantially higher than the first stiffness.

In some implementations, the electrical active layer is a thin film layer having a thickness of 500 microns (μm) or less.

In some implementations, the electrical active layer is a thick film layer having a thickness of more than 500 microns (μm) and less than 5 millimeters (mm).

In some implementations, the magnetoelectric magnetometer further includes at least one metal layer configured to allow a measurement of the electrical response.

In some implementations, the electric active layer has a surface area to volume ratio of at least 2:1.

In some implementations, the electrical response is a voltage change.

In some implementations, the magnetostrictive element and the electrical active layer are configured to amplify the magnetically induced stress in the magnetostrictive element to the electrical active layer by an amplification factor that is greater than one. In some implementations, the amplification factor is defined by 1/(2 tan θ).

In some implementations, the magnetostrictive element has a beam configuration.

A second example provides an apparatus that includes an electrical active means configured to provide an electrical response when subject to a mechanical stress; and a magnetostrictive means coupled to the electrical active means. The magnetostrictive means and the electrical active means are configured to amplify a magnetically induced stress in the magnetostrictive means to the electrical active means, resulting in an electrical response from the electrical active means.

In some implementations, the electrical active means is a piezoelectric layer.

A third example provides a magnetoelectric magnetometer that includes one or more electrical active layers, and one or more magnetostrictive layers. The magnetostrictive layer and electrical active layer are mechanically coupled via a mechanism for amplifying the magnetically induced stress in the magnetostrictive layer by the location of the mechanical coupling and the geometry of the electrical active layer.

In some implementations, the electrical active layers have opposite ends. The first and second ends of the electrical active layer are clamped. The electrical active layer have a center region between the ends. The magnetostrictive layer is bonded. The electrical active layers are polarized along the width between the ends. The stress induced by the magnetic field is applied along the length of the magnetostrictive layer and applied on the electrical active layer is amplified. In some implementations, the magnetometer includes two magnetostrictive layers. A first magnetostrictive layer is bonded on top of electrical active layer and the second magnetostrictive layer is bonded directly underneath electrical active layer.

In some implementations, the region of the electrical active layer not attached to magnetostrictive layer are tilted at a certain angle from horizontal. In some implementations, the angle is from ±20°.

In some implementations, the electrical active layers are individually comprised of two separate electrical active layers. The electrical active layers have opposite ends. The first end of first electrical active layer and second end of second electrical active layer are clamped. The second end of first electrical active layer and the first end of second electrical active layer are mechanically attached to a magnetostrictive layer.

In some implementations, the electrical active layers have opposite ends. The first and second ends of the electrical active layer are clamped. The electrical active layer have a center region between the ends. The magnetostrictive layer is bonded. The electrical active layers are polarized along the thickness of the electrical active layers. The stress induced by the magnetic field applied along the length of the magnetostrictive layer and applied on the electrical active layer is amplified.

In some implementations, the mechanism for amplifying provides a mechanical advantage amplification that ranges from 2:1 to 100:1.

In some implementations, the mechanism for amplifying the magnetically induced stress includes a lever with a pivot point attached to a rotatable hinge, the electrical active layer attached to one end of the lever along the length, and the magnetostrictive layer attached to the opposite end of the lever along the length.

In some implementations, the mechanism for amplifying the magnetically induced stress includes two interlocking gears, the magnetostrictive layer attached to drive a first gear, and the piezoelectric layer attached to be driven by a second gear.

In some implementations, the mechanism for amplifying the magnetically induced stress includes two high surface friction wheels, the magnetostrictive layer attached to drive a first wheel, and the electrical active layer attached to be driven by a second wheel.

In some implementations, the electrical active layer comprises of a monolithic electrical active layer.

In some implementations, the electrical active layer comprises of a piezoelectric fiber composite.

In some implementations, the electrical active layer includes at least one material selected from: a piezoelectric polymer, a piezoelectric ceramic, a piezoelectric single crystal and aluminum nitride.

In some implementations, the magnetostrictive layer comprises of at least one material selected from: Terfenol-D, Galfenol, and Metglas.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some implementations feature a magnetoelectric magnetometer that includes a first magnetostrictive element and a piezoelectric layer (e.g., electrical active element/layer). The piezoelectric layer (e.g., electrical active means, piezoelectric means) may be a piezoelectric film layer. The film layer may be a thin film layer or a thick film layer. The first magnetostrictive element (e.g., magnetostrictive means) is coupled (e.g., mechanically) to the piezoelectric layer. The first magnetostrictive element and the piezoelectric layer are configured to utilize mechanical advantage to enhance the magnetic field sensitivity of the magneto electric magnetometer. In some implementations, the magnetic field sensitivity of the magnetoelectric magnetometer relates to how precisely the magnetoelectric magnetometer is capable of measuring/detecting a change in magnetic field. In some implementations, the first magnetostrictive element has a beam configuration.

The first magnetostrictive element and the piezoelectric layer are configured/adapted/configured to utilize mechanical advantage to convert magnetic energy into electric energy. In some implementations, the mechanical advantage provides stress amplification by coupling (e.g., affixing, clamping) a first end portion of the piezoelectric layer and a second end portion of the piezoelectric layer, so that the first and second end portions are fixed, while allowing a third portion of the piezoelectric layer to move and/or bend relative to the first and second end portions when a magnetic field is applied and/or present. The third portion may be a portion of the piezoelectric layer between the first end portion and the second end portion of the piezoelectric layer. In some implementations, the magnetostrictive element is coupled to the third portion of the piezoelectric layer. In some implementations, the piezoelectric layer may have an increase in surface area to volume ratio (e.g., 2:1 to 20:1). In some implementations, the piezoelectric layer may be configured as a beam that has a high aspect ratio.

Some implementations may also include a second magnetostrictive element. The second magnetostrictive element may be coupled to the piezoelectric layer such that the piezoelectric layer is positioned between the first and second magnetostrictive elements (e.g., between faces of the first and second magnetostrictive elements). The first magnetostrictive element and/or the second magnetostrictive element may be a magnetostrictive layer in some implementations.

### Exemplary Elements and Configuration of a Magnetoelectric Magnetometer

Having provided an overview of a magnetoelectric magnetometer, various elements and/or configurations of a magnetoelectric magnetometer will now be described below. After describing the various elements and configurations of a magnetoelectric magnetometer, a description of the properties of the magnetoelectric magnetometer, as well as how the elements and configurations of the magnetoelectric magnetometer function will be described.

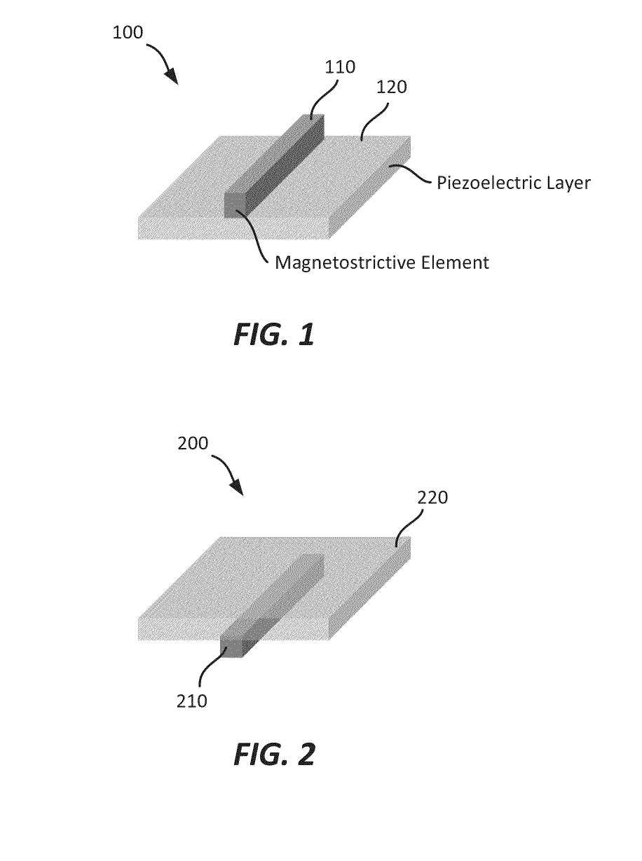

FIG. 1 illustrates a magnetoelectric magnetometer according to some implementations. As shown in FIG. 1, the magnetoelectric magnetometer 100 includes a magnetostrictive element 110 and a piezoelectric layer 120. The magnetostrictive element 110 is coupled to the piezoelectric layer 120. In some embodiments, the magnetostrictive element 110 is coupled to the piezoelectric layer 120 via mechanical bonding (e.g., epoxy bond). In some implementations, the magnetostrictive element 110 may be coupled to the piezoelectric layer 120 by depositing the magnetostrictive element 110 using Micro Electro Mechanical Systems (MEMS) fabrication techniques

A magnetostrictive element (e.g., magnetostrictive means) may be a ferromagnetic material that is capable of converting magnetic energy into mechanical energy. Examples of ferromagnetic magnetostrictive materials include Terfenol-D (TbxDy1-xFe2), Galfenol (Fe1-xGax) and Metglas 2605SC.

A piezoelectric layer and/or piezoelectric element (e.g., electrical active means, piezoelectric means) may be a material that is capable of converting mechanical energy into electrical energy. More specifically, piezoelectric materials are materials that exhibit an electrical polarization when subjected to a mechanical stress, resulting in an induced voltage. Examples of piezoelectric materials include single crystal piezoelectric (e.g. PMN-PT), piezoelectric polymer (e.g. PVDF), piezoelectric ceramic (e.g. PZT) or aluminum nitride. These materials may be in monolithic or composite form and in bulk or film form. In some implementations, a piezoelectric layer and/or a piezoelectric element is an example of an electrical active element. In some implementations, an electrical active element is a material that exhibits electrical polarization when subjected to a mechanical stress. In some implementations, an electrical active element (e.g., electrical active layer) is a material that builds up an electrical charge when subjected to a mechanical stress.

The principle behind the conversion from magnetic energy to mechanical energy and then to electrical energy will be further described in the next section.

FIG. 1 illustrates that the first magnetostrictive element 110 is positioned above the piezoelectric layer 120. However, in some implementations, a magnetostrictive element may be positioned differently relative to a piezoelectric layer. For example, the magnetostrictive element may be positioned below the piezoelectric layer, as shown in FIG. 2. Specifically, FIG. 2 illustrates a magnetoelectric magnetometer 200 that includes a magnetostrictive element 210 and a piezoelectric layer 220. The magnetostrictive element 210 is coupled (e.g., via epoxy bond) to the piezoelectric layer 220 in such a way that the magnetostrictive element 210 is positioned below the piezoelectric layer 220.

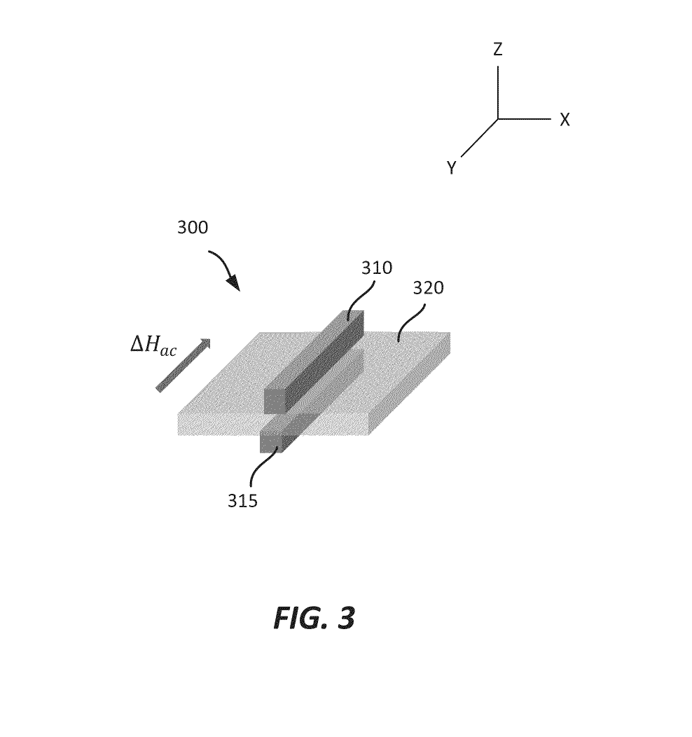

In some embodiments, a magnetoelectric magnetometer may include more than one magnetostrictive element. FIG. 3 illustrates an example of a magnetoelectric magnetometer with several magnetostrictive elements. As shown in FIG. 3, the magnetoelectric magnetometer 300 includes a first magnetostrictive element 310, a second magnetostrictive element 315, and a piezoelectric layer 320. The first magnetostrictive element 310 is coupled to the piezoelectric layer 320 and the second magnetostrictive element 315 is coupled to the piezoelectric layer 320. The piezoelectric layer 320 is located between the first magnetostrictive element 310 and the second magnetostrictive element 315.

FIGS. 1-3 illustrate the magnetostrictive element (e.g., magnetostrictive element 210) being located at the center of the piezoelectric layer (e.g., piezoelectric layer 220). However, different implementations may position the magnetostrictive element differently relative to the piezoelectric layer. In some implementations, the magnetostrictive element may be positioned closer to one end of the piezoelectric layer and does not necessarily need to be at the center of piezoelectric layer.

The dimensions of the piezoelectric layer and the magnetostrictive element may be defined by length (e.g., first dimension), width (e.g., second dimension) and thickness (e.g., third dimension). As shown in FIG. 3, the length is defined along the Y-direction, the width is defined along the X-direction, and the thickness is defined along the Z-direction. However, the dimensions of the piezoelectric layer and/or magnetostrictive element may be defined differently.

In addition, the length of the magnetostrictive element shown in FIGS. 1-3 extends along the entire length (Y-direction) of the piezoelectric layer. However, in some implementations, the length of the magnetostrictive element may extend for part of the length of the piezoelectric layer instead of the entire length of the piezoelectric layer.

In some embodiments, portions of the ends of the piezoelectric layer are fixed. That is, portions of the ends of the piezoelectric layer are clamped so the portions of the ends remain fixed, while still allowing portion of the piezoelectric layer between the ends to move and/or bend. In some implementations, the clamping or affixing of portions of the ends of the piezoelectric layer is done to provide mechanical advantage (e.g., stress amplification), which will be further described in the next section.

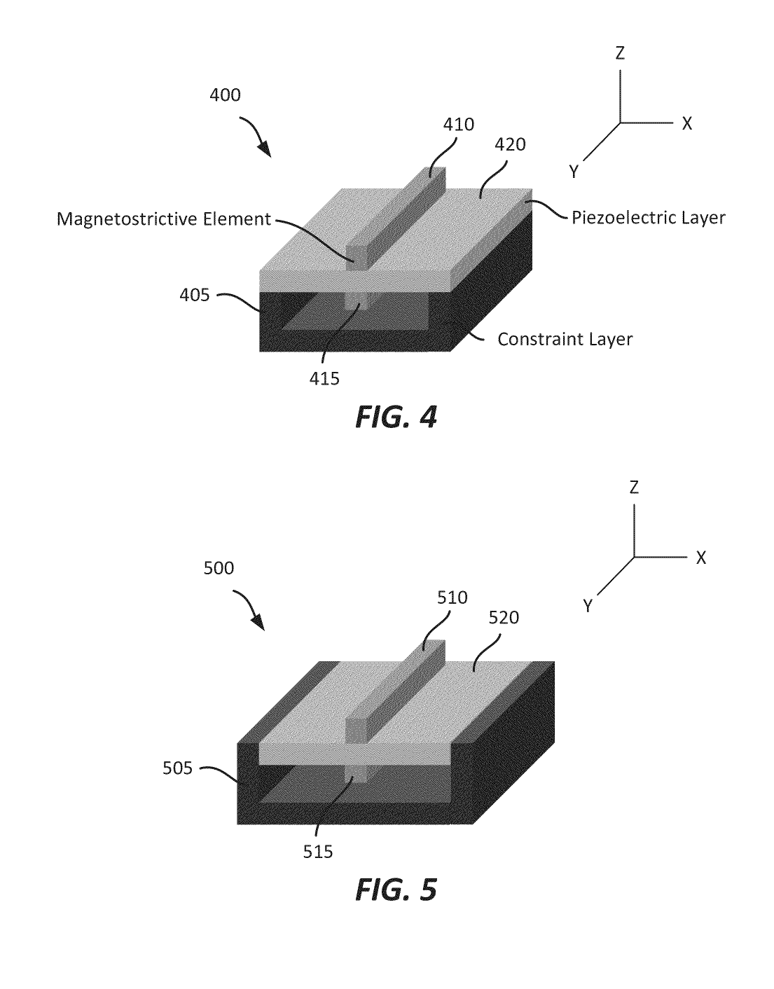

Different implementations may clamp portions of the ends of the piezoelectric layer differently. FIGS. 4-5 illustrate different ways that portions of the ends of a piezoelectric layer may be held fixed and/or clamped.

FIG. 4 illustrates a magnetoelectric magnetometer 400 that includes portions of the ends of a piezoelectric layer that are fixed. FIG. 4 is similar to FIG. 3, except that FIG. 4 also includes a constraint layer 405. As shown in FIG. 4, the magnetoelectric magnetometer 400 includes the constraint layer 405, a first magnetostrictive element 410, a second magnetostrictive element 415, and a piezoelectric layer 420. The portions of the ends (or ends) of the piezoelectric layer 420 may be held fixed by coupling them to the constraint layer 405. In FIG. 4, portions of the ends of the piezoelectric layer 420 are coupled to the top of the end portions of the constraint layer 405. In some implementations, portions of the ends of the piezoelectric layer 420 are bonded (e.g., using epoxy) to the top of the end portions of the constraint layer 405.

The displacement (e.g., moving, bending) of the magnetostrictive elements 410 and 415, and the piezoelectric layer 420 may be along any direction (e.g., Y-axis, X-axis, Z-axis). However, in some implementations, the displacement along the length (e.g., Y-axis) of the magnetostrictive element may provide the best sensitivity for the magnetometer.

FIG. 5 illustrates another example of how portions of the ends of a piezoelectric layer may be held fixed (or clamped). As shown in FIG. 5, the magnetoelectric magnetometer 500 includes a constraint layer 505, a first magnetostrictive element 510, a second magnetostrictive element 515, and a piezoelectric layer 520. The portions of the ends (or ends) of the piezoelectric layer 520 are coupled (e.g., bonded using epoxy) to the sides of portions of the ends of the constraint layer 505. In some implementations, a combination of the coupling of the piezoelectric layer to the constraint layer shown in FIGS. 4-5 may be used. That is, portions of the ends of the piezoelectric layer may be coupled to the side and to the top of the constraint layer in some implementations.

The displacement (e.g., moving, bending) of the magnetostrictive elements 510 and 515, and the piezoelectric layer 520 may be along any direction (e.g., Y-axis, X-axis, Z-axis). However, in some implementations, the displacement along the length (e.g., Y-axis) of the magnetostrictive element may provide the best sensitivity for the magnetometer.

Different implementations may use different materials for the magnetostrictive element, piezoelectric layer, and the constraint layer described above. Some implementations may use material for the magnetostrictive element(s), piezoelectric layer, and/or the constraint layer to achieve a particular stiffness. In some implementations, the stiffness of an element, component, and/or layer relates to the shape, dimension and elastic modulus (e.g., Young's Modulus) of the material used for the element, component, and/or layer. In some implementations, the constraint layer is made of a material that results in the constraint layer having a stiffness that is significantly higher than the stiffness of the piezoelectric layer. Some implementations may select the dimensions and materials of the magnetostrictive element(s) so that the stiffness of the magnetostrictive element(s) matches, closely matches or is near (e.g., within a range) the stiffness of the piezoelectric layer. It should also be noted that the piezoelectric layer may be any electric active element that exhibits electrical polarization when subjected to a mechanical stress, and/or that builds up an electrical charge when subjected to a mechanical stress.

In addition, the magnetostrictive element, piezoelectric layer, and the constraint layer may have different thicknesses. In some implementations, the piezoelectric layer may be a piezoelectric film layer. The film layer may be a thin film layer or a thick film layer. In some implementations, a thin film layer may have a thickness (e.g., height, along Z-axis) of 500 microns (μm) or less. In some implementations, a thick film layer may have a thickness (e.g., height, along Z-axis) greater than 500 microns (μm) but less than 5 millimeters (mm). Different implementations may use different techniques to manufacture the magnetoelectric magnetometer. In some implementations, the magnetometer may be manufactured by using Micro Electro Mechanical Systems (MEMS) fabrication methods.

Having described various elements and/or configurations of a magnetoelectric magnetometer, the properties and functionalities of the magnetoelectric magnetometer will now be described below.

### Exemplary Magnetoelectric Magnetometer Properties

As discussed above, some implementations of a magnetoelectric magnetometer are made of a magnetoelectric composite that relies on the mechanical coupling between a magnetostrictive material and a piezoelectric material to transduce magnetic energy to electrical energy. This electrical energy can be measured, which allows the magnetoelectric magnetometer to measure and/or detect the magnetic field vector and/or changes in the magnetic field vector.

More specifically, magnetostrictive materials exhibit a strain when subjected to an applied magnetic field, while the piezoelectric materials exhibit an induced electric field when strained. When a magnetostrictive material and a piezoelectric material are mechanically coupled (e.g. via epoxy bond) magnetic energy can be converted to electrical energy. In other words, an applied magnetic field causes a magnetostrictive material to strain (e.g., move and/or bend), the straining (e.g., movement and/or bending) of the magnetostrictive material causes the piezoelectric material to strain as well (since the piezoelectric material is coupled to the magnetostrictive material). The straining of the piezoelectric material consequently induces an electrical field (e.g., current and/or voltage), which can be measured. Thus, for a given magnetic field, a magnetoelectric composite that can induce a large electric field is more sensitive than another magnetoelectric composite that induces a small electric field (relative to the large electric field).

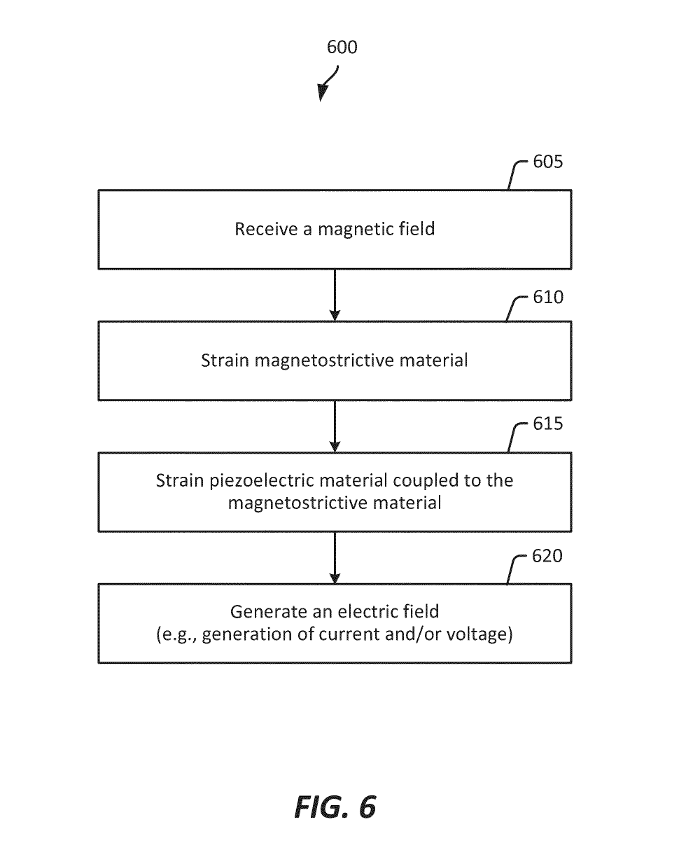

The above process is expressed by FIG. 6, which conceptually illustrates a flow diagram of a magnetic field being converted into an electrical field. The process of FIG. 6 may be performed by a magnetoelectric magnetometer in some implementations. As shown in FIG. 6, the process receives (at 605) a magnetic field. In some implementations, receiving a magnetic field includes detecting an applied magnetic field. The process further strains (at 610) a magnetostrictive material. In some implementations, straining the magnetostrictive material includes bending and/or moving a magnetostrictive layer of the magnetostrictive magnetometer in response to the magnetic field. The process strains (at 615) a piezoelectric material of the magnetostrictive magnetometer. The piezoelectric material is coupled to the magnetostrictive material. In some implementations, straining the piezoelectric material is in response to the straining of the magnetostrictive material. In some implementations, straining the piezoelectric material includes bending and/or moving a piezoelectric layer of the magnetostrictive magnetometer. The process generates (at 620) an electric field in response to the straining of the piezoelectric material. In some implementations, the generated electric field may be measured via an induced current and/or voltage. The induced current and/or voltage may be induced in a metal material (e.g., metal layers) of the magnetoelectric magnetometer. The metal material may be coupled to the piezoelectric layer and/or magnetostrictive material in some implementations.

One of the factors that play a role in the sensitivity of a magnetometer is the voltage coefficient (α_{ME}) of a magnetoelectric (ME) magnetometer. The voltage coefficient is a property of the magnetometer that quantifies the induced/generated voltage (V_{ME}) for a given applied magnetic field (ΔH_{αc}) and for a given thickness (t) of the piezoelectric layer, (see e.g., FIG. 3) and can be expressed by the following Equation 1:

α_{ME}=V_{ME}/(ΔH_{αc}·t) (1)

In addition, the voltage coefficient (α_{ME}) is a function of magnetostrictive and piezoelectric material properties, and may be expressed by the following Equation 2:

$${α}_{ME} = \frac{{d}_{31}}{ɛ} \cdot {k}_{c} \cdot {d}_{33}^{m} \qquad ( 2 )$$

where ε is the permittivity of the piezoelectric layer, d₃₁ and d₃₃^{m} are the piezoelectric and piezomagnetic strain coefficients, respectively. d₃₁/ε is termed the piezoelectric voltage coefficient (g₃₁) and essentially defines the change in polarization, and as a consequence induced voltage, in the piezoelectric layer due to a change in applied stress. The piezomagnetic strain coefficient defines the change in strain in the magnetostrictive element/layer due to an applied magnetic field. Additionally, k_{c} is the coupling coefficient (or efficiency of mechanical energy transfer) between the magnetostrictive and piezoelectric layers. Generally speaking, a higher piezoelectric voltage coefficient for the magnetometer results in a magnetometer with higher sensitivity.

The sensitivity of a magnetometer may be limited by the signal to noise ratio (SNR) of the magnetometer. In some implementations, the SNR of a magnetometer may be defined by the following Equation 3:

SNR=(g₃₁·d₃₁·k_{c}²·(d₃₃^{m})²·H_{αc}²·t·A·ω)/(4·k_{g}T·Δf·tan δ), (3)

where A is the cross-sectional area of the magnetometer (e.g., area of the piezoelectric layer), ω is the angular frequency, k_{B} is Boltzmann's constant, Δf is the noise bandwidth and tan δ is the dissipation factor. As can be seen from Equation 3, the SNR can be maximized in some implementations, by (1) optimizing the piezoelectric and magnetostrictive material properties (g₃₁, d₃₁, d₃₃^{m}, and tan δ) and/or (2) by increasing the volume (i.e., t·A) of the piezoelectric layer. For many applications, size and/or form factor are constraints, therefore increasing the area and/or volume of the piezoelectric layer and in turn the area and/or volume of the magnetoelectric magnetometer may not be a viable, practical and/or cost effective option to increase the SNR of the magnetometer. In such instances, optimizing the piezoelectric and magnetostrictive materials properties may provide a cost effective solution to increasing the SNR of the magnetometer. Thus, for a given area and/or volume, one aspect of the present implementation may provide an SNR that is equal to or better than the SNR of a magnetometer that has a larger area or volume. In some implementations, this may include providing a magnetoelectric magnetometer that has the highest possible SNR per area and/or volume for a magnetoelectric magnetometer (e.g., highest possible SNR per area and/or volume of a piezoelectric layer).

In some implementations, the noise floor of a magnetoelectric magnetometer may be expressed by the following Equation 4:

Noise Floor=1/Square Root(SNR) (4)

From Equation 4, it is clear that maximizing the SNR value of the magnetometer decreases the noise floor of the magnetometer, thus allowing the magnetometer to measure/detect smaller and/or lower signals. The ability to detect these smaller and/or lower signals is related to the sensitivity of the magnetometer.

### Exemplary Stress Amplification to Increase Sensitivity of Magnetometer

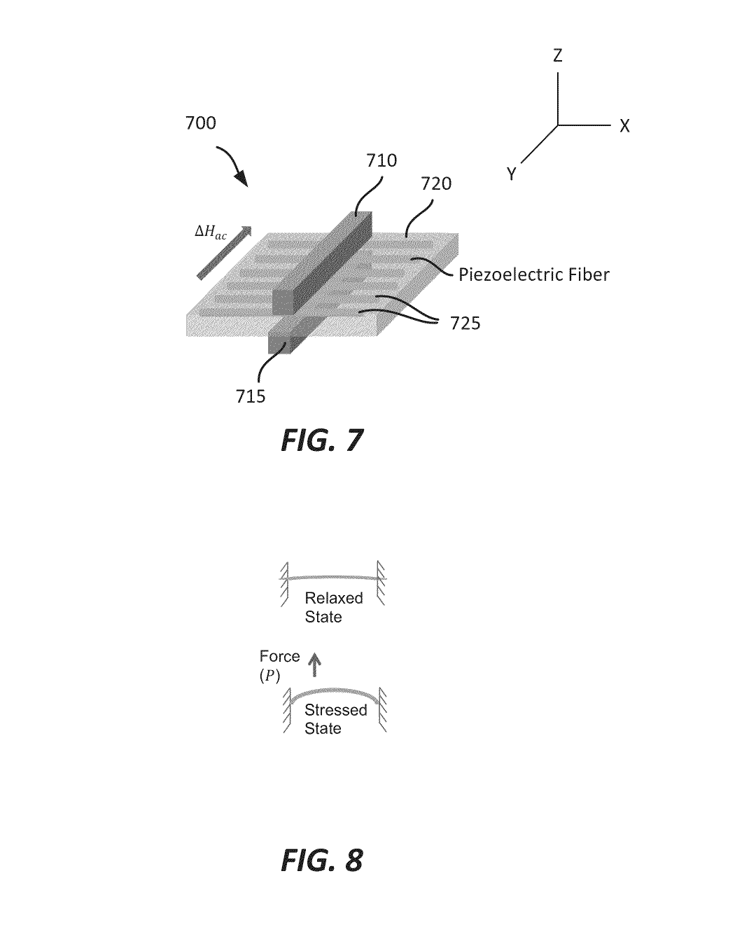

As described above, mechanical advantage and/or leverage may be used to increase the sensitivity of a magnetometer. An example of mechanical advantage is stress amplification, which will be described with reference to FIGS. 7-10.

FIG. 7 is similar to FIG. 3, except that the piezoelectric layer is a composite of piezoelectric fibers and a matrix (e.g. polymer). As shown in FIG. 7, the magnetoelectric magnetometer 700 includes a first magnetostrictive element 710, a second magnetostrictive element 715, and a piezoelectric layer 720. The piezoelectric layer 720 includes several piezoelectric fibers 725 that are aligned along the width (X-direction) of the piezoelectric layer 720.

Under stress amplification, a mechanical advantage is essentially used to amplify the piezoelectric strain coefficient of the piezoelectric layer. Referring to FIG. 7, some implementations may use piezoelectric fibers that are aligned along the width (X-direction) of a piezoelectric composite layer (e.g., piezoelectric layer 720). Magnetostrictive elements (e.g., magnetostrictive elements 710-715) are coupled (e.g., mechanically bonded using epoxy) to the top and bottom portions of the piezoelectric layer. As shown in FIG. 7, the piezoelectric fibers 725 are aligned perpendicularly to the long axis of the magnetostrictive layer (i.e., along the direction of the applied magnetic field, which is shown by the arrow). Additionally, the portions of the edges (or ends) of the piezoelectric fibers are clamped (not shown), which prevents the piezoelectric fibers from moving relative to each other.

When the magnetostrictive layer is magnetized along its long axis (along the Y-direction) due to the magnetic field, the force (P) transferred to the piezoelectric layer results in a bending of the piezoelectric fibers.

It should be noted that the displacement (e.g., moving, bending) of the magnetostrictive elements 710 and 715, the piezoelectric layer 720, and the fibers 725 may be along any direction (e.g., Y-axis, X-axis, Z-axis). However, in some implementations, the displacement along the length (e.g., Y-axis) of the magnetostrictive element may provide the best sensitivity for the magnetometer.

FIG. 8 illustrates how this bending may occur in some implementations. Specifically, FIG. 8 illustrates two states that the piezoelectric layer and/or fibers may be in. In one state, the piezoelectric layer and/or fibers are in a relaxed state. In this particular state, there is no applied magnetic field (or at least no detectable magnetic field) and thus there is no force being applied. In another state, the piezoelectric layer and/or fibers are in a stressed state. In this state, there is a force (e.g., due to magnetic field) that is being applied which causes the bending of the piezoelectric layer and/or fibers. In some implementations, this force is the force that is produced by the magnetostrictive element (due to displacement) when the magnetostrictive element is subject to a magnetic field in a particular direction (e.g., along the length of the magnetostrictive element).

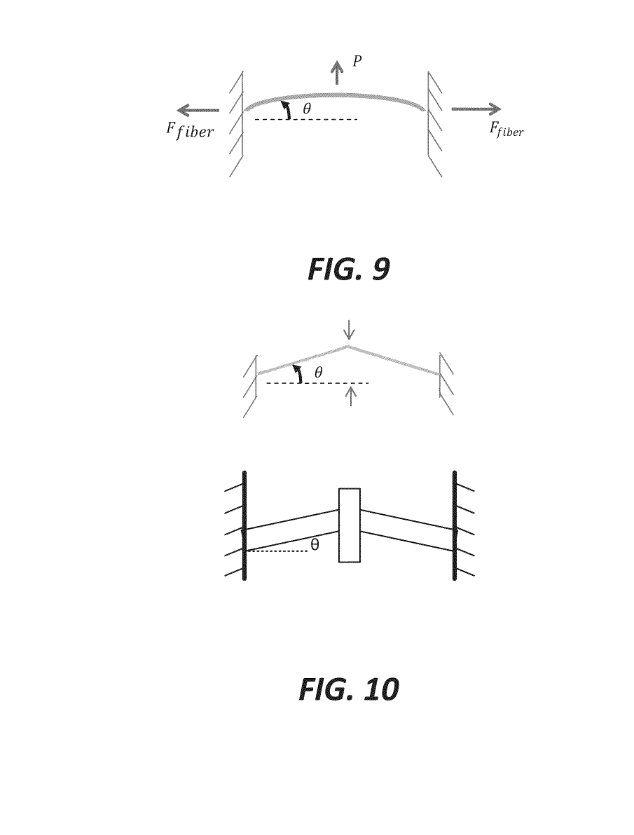

Referring to FIG. 9, this force (P) is amplified (because of the clamping of the ends of the piezoelectric layer and/or fibers) resulting in a force (F_{fiber}) along the direction of the piezoelectric fibers. In some implementations, the amplification factor (AF) is dependent on the angle θ, and is calculated as shown below in Equation 5.

$$\begin{matrix}AF = \frac{{F}_{fiber}}{P} = \frac{1}{2 tan θ} & ( 5 ) \\ {g}_{31}^{eff} = \frac{{d}_{31}^{eff}}{ɛ} = AF \cdot \frac{{d}_{31}}{ɛ} & ( 6 )\end{matrix}$$

The effective piezoelectric strain coefficient and, therefore, the piezoelectric voltage coefficient may be calculated as shown in Equation 6 above.

In some embodiments, the above approach provides high piezomagnetic strain coefficient and high permeability. Although, the above approach is described for a piezoelectric composite layer (with or without piezoelectric fibers), some implementations may use a monolithic piezoelectric layer.

To lower sensitivity of the magnetometer but potentially increase robustness, some implementations may use a piezoelectric layer that is initially angled in the relaxed state. More specifically, the piezoelectric fibers may be angled from the horizontal position to provide less stress amplification than a piezoelectric layer and/or fiber that is entirely horizontal in a relaxed state.

FIG. 10 illustrates an example of an angled piezoelectric layer. As shown in FIG. 10, in a relaxed state (when there is no or undetectable magnetic field) the piezoelectric layer is offset horizontally by an angle θ. In some implementations, this angle may be in the range of ±20°. Although in some implementations, the angle may be more than 20° and/or less than −20°.

### Exemplary Additional Implementations

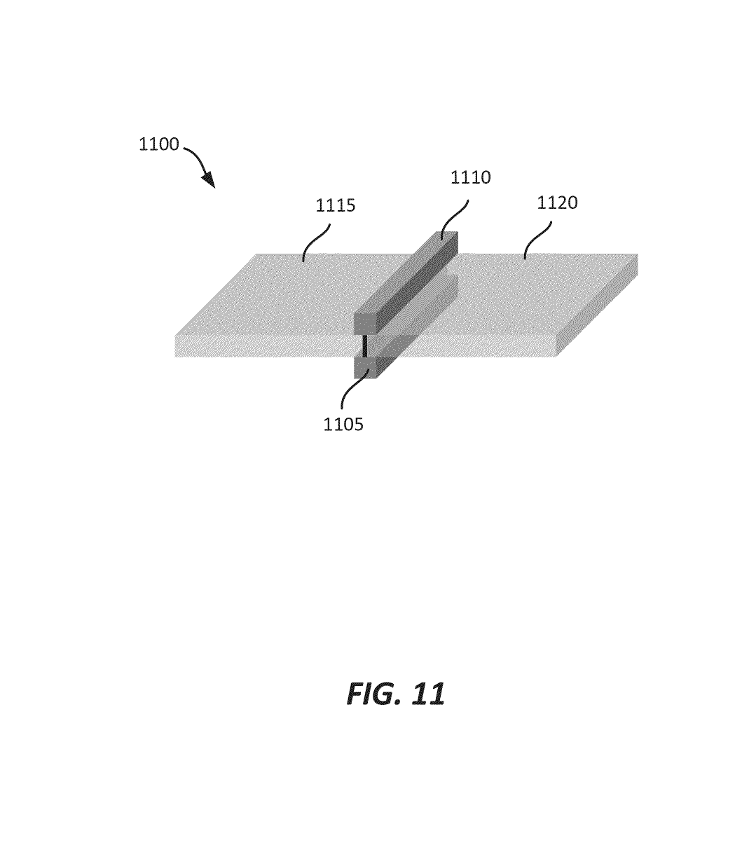

As mentioned above, one way to achieve higher sensitivity in a magnetometer is to reduce/lower the noise floor of the magnetometer. However, one issue that may affect the noise floor and may need to be accounted for is the pyroelectric noise of the magnetometer. A pyroelectric effect is a thermally induced electric field exhibited by some materials. A pyroelectric coefficient is a value that quantifies the amount of charge produced as a function of temperature. Ideally, the pyroelectric coefficient should be minimized so that it does not affect the reading of the magnetic field. One way to reduce, minimize or mitigate the effects of pyroelectric noise is to use two identical piezoelectric layers that are mechanically disconnected, thermally connected, and electrically connected in reverse (e.g., reverse polarity). FIG. 11 illustrates an example of such a configuration.

As shown in FIG. 11, the magnetoelectric magnetometer 1100 includes a first magnetostrictive element 1105, a second magnetostrictive element 1110, a first piezoelectric layer 1115, and a second piezoelectric layer 1120. The first piezoelectric layer 1115 and the second piezoelectric layer 1120 are mechanically disconnected, thermally connected, and electrically connected (in reverse polarity). Moreover, FIG. 11 illustrates that the first and second magnetostrictive elements 1105-1110 are positioned where the first piezoelectric layer 1115 and the second piezoelectric layer 1120 meet. In some implementations, this configuration of the magnetoelectric magnetometer helps mitigate the effects of temperature change (e.g., it provides temperature compensation).

In some embodiments, the magnetostrictive material may be subject to a magnetic field from a permanent magnet that is positioned near (or within) the magnetometer. The permanent magnet may provide a bias direct current (DC) magnetic field to maximize the piezomagnetic coefficient of the magnetostrictive element(s).

In lieu of or in addition to a permanent magnet, some implementations may use an exchange biasing scheme to maximize the piezomagnetic coefficient of the magnetostrictive element(s). In such an approach, magnetostrictive layers may be sequentially deposited in between antiferromagnetic layers (e.g., manganese iridium), which may act as an internal magnet.

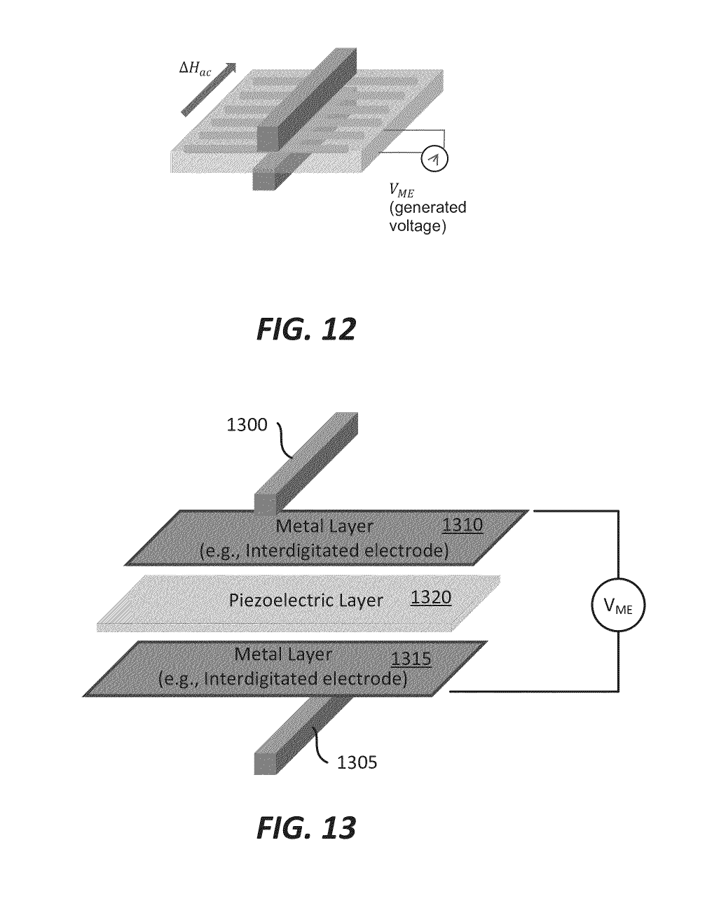

FIG. 12 illustrates how voltage may be measured, and consequently how a magnetic field may be measured and/or detected. Thus, another way to increase the sensitivity of the magnetometer is to increase the sensitivity of the voltage reading. One approach to increasing voltage reading sensitivity is to use interdigitated electrodes (which is a form of a metal layer). In some implementations, voltage reading is done between metal layers that may be coupled to the piezoelectric layer. The use of interdigitated electrodes allows for a piezoelectric poling method for increasing the response out of the piezoelectric layer. In some implementations, this is done by using the g₃₃ coefficient of the piezoelectric layer instead of the g₃₁ coefficient of the piezoelectric layer. The g₃₃ coefficient may be significantly higher than the gₐₜ coefficient of the piezoelectric layer in some implementations. The first subscript value refers to the direction of the applied stress, while the second subscript value refers to the direction of the induced voltage. In essence, one or more metal layers (e.g., the interdigitated electrodes) are positioned on top and/or below the piezoelectric layer, as shown in FIG. 13. The magnetostrictive elements 1300 & 1305 would be positioned on top or below the metal layers 1310 & 1315 (e.g., interdigitated electrodes). In some implementations, a set of pins may be positioned on a first metal layer 1310 and a second metal layer 1315 to measure the induced voltage. As shown in FIG. 13, a piezoelectric element/layer 1320 is positioned between the first metal layer 1310 and the second metal layer 1315.

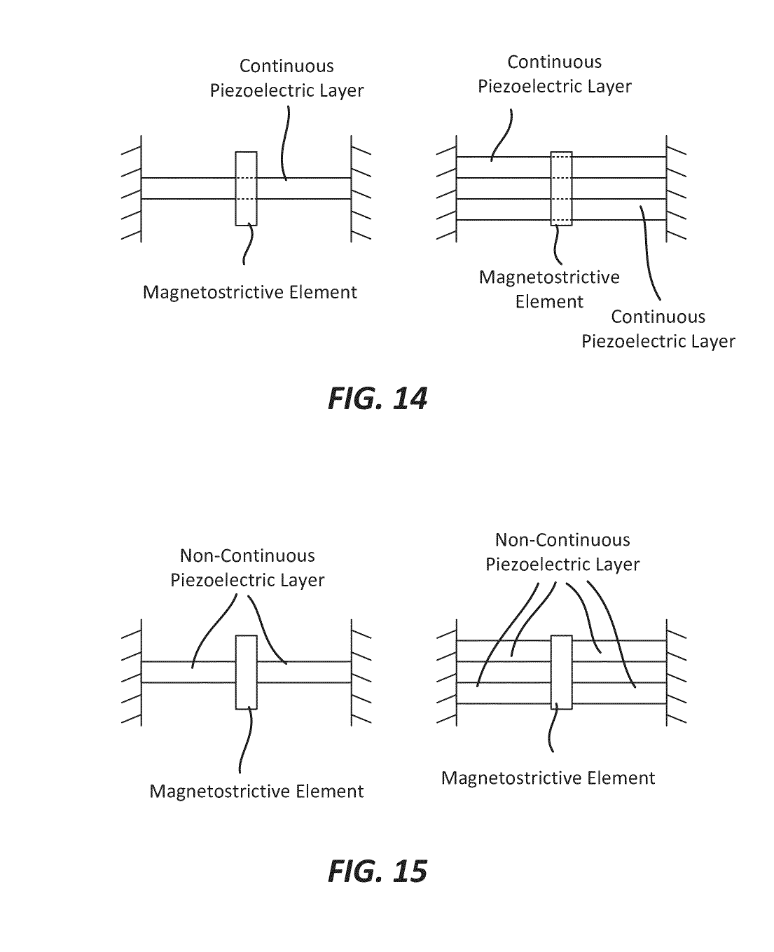

In the above description various implementations are described for a magnetostrictive magnetometer. However, some implementations may use different elements and/or configurations of the above described magnetometer. For example, some implementations may use one continuous piezoelectric layer while other implementations may use a non-continuous piezoelectric layer (layer having multiple piezoelectric elements). FIG. 14 illustrates examples of a continuous piezoelectric layer(s) from end to end. However, in some implementations, non-continuous piezoelectric layer(s) may be used, as shown in FIG. 15. In such instances, one end of the non-continuous piezoelectric layer may be fixed (e.g., bonded to constraint layer), while another end of the non-continuous piezoelectric layer may coupled to a magnetostrictive element. In the case where a non-continuous piezoelectric layer is used, the magnetostrictive element may be located where there is a break in the continuity of the piezoelectric layer.

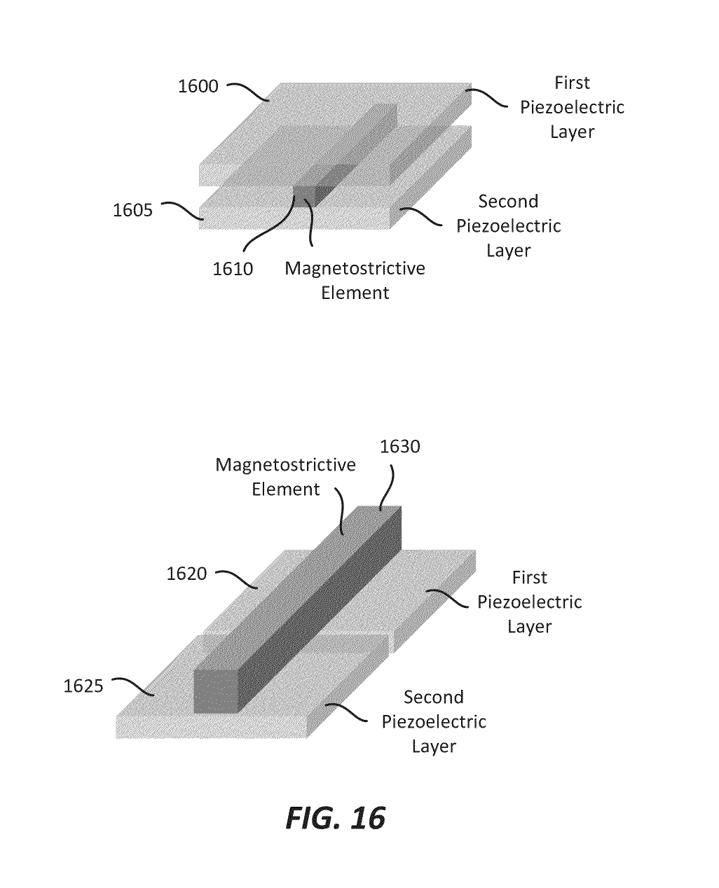

Some implementations of the magnetometer may include two piezoelectric layers and one magnetostrictive element. The two piezoelectric layers may be separate from each other but on the same layer in some implementations. The two piezoelectric layers may also be on different horizontal layers and positioned in such a way as to have a magnetostrictive element in between them. Examples of such configurations are shown in FIG. 16. In a first configuration shown in FIG. 16, a first piezoelectric element 1600 is coupled to a first portion (e.g., top portion) of a magnetostrictive element 1610, and a second piezoelectric element 1605 is coupled to a second portion (e.g., bottom portion) of the magnetostrictive element 1610. In a second configuration shown in FIG. 16, a first piezoelectric element 1620 is coupled to a first portion (e.g., first bottom portion) of a magnetostrictive element 1630, and a second piezoelectric element 1625 is coupled to a second portion (e.g., second bottom portion) of the magnetostrictive element 1630. As shown in the second configuration, the first and second piezoelectric elements 1620 & 1625 are separate from each other but on the same plane. In some implementations, the first and second piezoelectric elements 1620 & 1625 are piezoelectric layers (e.g., piezoelectric thin film layer). Although metal layers are not shown in the configurations shown in FIG. 16, in some implementations, metal layers (e.g., electrodes) may be provided to the piezoelectric elements in a manner similar to what is shown in FIG. 13.

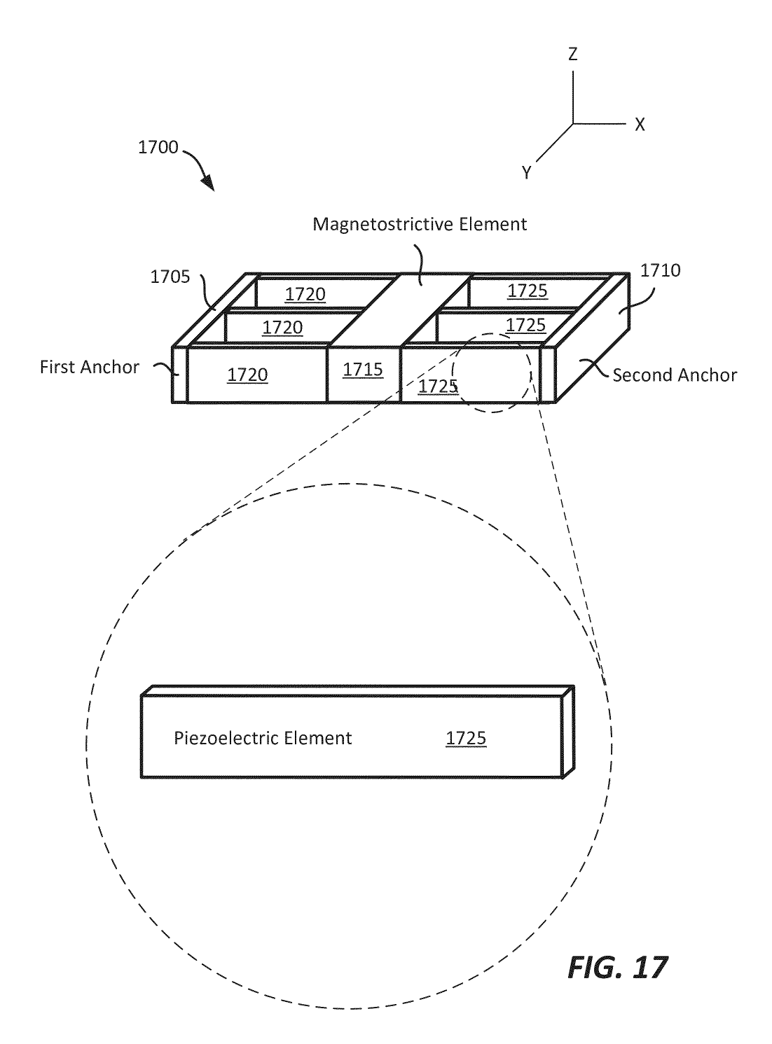

In some implementations, a magnetometer with better/higher sensitivity may be achieved by increasing the surface area to volume ratio of the piezoelectric material. FIG. 17 illustrates an example of such a magnetometer. Specifically, FIG. 17 illustrates a magnetometer 1700 that includes a first anchor 1705, a second anchor 1710, a magnetostrictive element 1715 (e.g., magnetostrictive actuator), a first set of piezoelectric elements 1720, and a second set of piezoelectric elements 1725. In some implementations, the first anchor 1705 (e.g., first constraint) and the second anchor 1710 (e.g., second constraint) are fixed elements of the magnetometer 1700.

The first anchor 1705 is coupled to the first set of piezoelectric elements 1720. The first set of piezoelectric elements 1720 is coupled to the magnetostrictive element 1715. Specifically, a first portion (e.g., first end portion) of the first set of piezoelectric elements 1720 is coupled to the first anchor 1705, and a second portion (e.g., second end portion) of the first set of piezoelectric elements 1720 is coupled to a first portion of the magnetostrictive element 1715.

The second anchor 1710 is coupled to the second set of piezoelectric elements 1725. The second set of piezoelectric elements 1725 is coupled to the magnetostrictive element 1715. Specifically, a first portion (e.g., first end portion) of the second set of piezoelectric elements 1725 is coupled to the second anchor 1710, and a second portion (e.g., second end portion) of the second set of piezoelectric elements 1725 is coupled to a second portion of the magnetostrictive element 1715.

In some implementations, the magnetostrictive element 1715 and the piezoelectric layers (e.g., piezoelectric elements 1720 and/or 1725) are adapted/configured to amplify a magnetically induced stress in the magnetostrictive element 1715 to the piezoelectric layers 1720 and/or 1725, resulting in an electrical response from the piezoelectric layers 1720 and/or 1725. In some implementations, the first end portions of the piezoelectric layers 1720 and 1725 are fixed, while a third portion (e.g., portion between the first portion and the second portion) of the piezoelectric layers 1720 and 1725 is free to bend. In some implementations, the magnetostrictive element 1715 may displace (e.g., move, bend) in response to a magnetic field. In some implementations, some portions of the piezoelectric layers 1720 and 1725 may displace (e.g., move, bend) when the magnetostrictive element 1715 is displaced.

FIG. 17 illustrates that each of the first and second sets of piezoelectric elements 1720 and 1725 includes three (3) piezoelectric elements. However, different implementations may have a different number of piezoelectric elements. FIG. 17 also illustrates that each piezoelectric element has a width (e.g., dimension along Y-axis), a height (e.g., dimension along Z-axis), and a length (e.g., dimension along X-axis).

FIG. 17 further illustrates that each piezoelectric element has a beam like structure. In some implementations, this configuration of the piezoelectric elements increases the surface area to volume ratio of the piezoelectric element, which increases the sensitivity of the magnetometer. In some implementations, the surface area of the piezoelectric element is the surface area along the Z-X plane of the piezoelectric element, as shown in FIG. 17. However, in some implementations, the surface area of the piezoelectric element may be on a different plane. In some implementations, the surface area of the piezoelectric element is the total surface area of the piezoelectric element (e.g., first surface area+second surface area+third surface area, etc. . . . ). In some implementations, the surface area, is the surface area (e.g., total surface area) of all the piezoelectric elements in the magnetometer. In some implementations, the volume is the amount of space that the piezoelectric element occupies (e.g., width×length×height). In some implementations, the volume is the amount of space that one or more (e.g., all) piezoelectric elements occupy in the magnetometer. In some implementations, the volume is the amount of space that one or more (e.g., all) piezoelectric elements (including any gaps in between) occupy in the magnetometer. For example, if there are any air gaps in between two piezoelectric elements (e.g., as shown in FIG. 17), the air gap would be part of the volume that is used to calculate the surface area to volume ratio. In some implementations, the surface area to volume ratio of piezoelectric element may be between 2:1 and 20:1.

In some implementations, when metal layers (e.g., electrodes) are coupled to the piezoelectric elements, the surface area, space and/or volume occupied may be considered when determining the surface area to volume ratio. It should be noted that the space and/or volume occupied by the magnetostrictive element shall be excluded when determining the surface area to volume ratio.

It should be noted that the displacement (e.g., moving, bending) of the magnetostrictive element 1715, and the piezoelectric elements 1720 and 1725 (or portions of the piezoelectric elements) may be along any direction (e.g., Y-axis, X-axis, Z-axis). However, in some implementations, the displacement along the length (e.g., Y-axis) of the magnetostrictive element 1715 may provide the best sensitivity for the magnetometer.

In some implementations, metal layers that are configured to operate as electrodes may also be added to the magnetometer of FIG. 17. Different implementations may provide these metal layers on different portions (e.g., surface) of one or more of the piezoelectric elements.

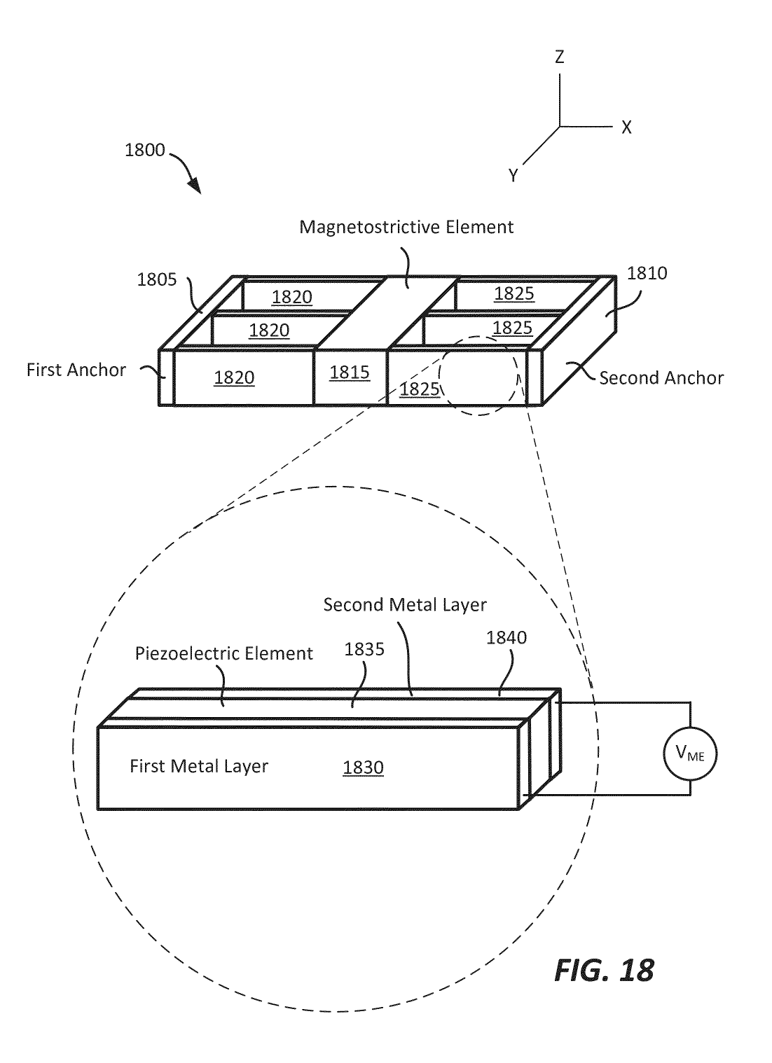

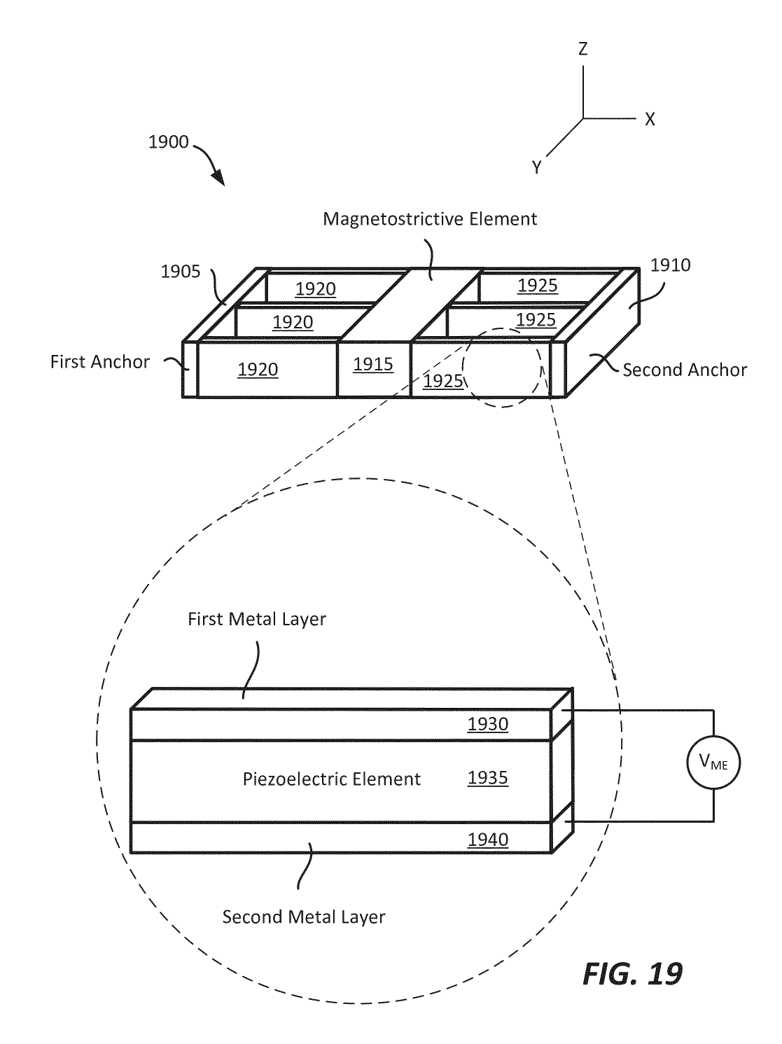

FIGS. 18 and 19 illustrate examples of where the metal layers may be provided. FIG. 18 illustrates a magnetometer 1800 that includes a first anchor 1805, a second anchor 1810, a magnetostrictive element 1815 (e.g., magnetostrictive actuator), a first set of piezoelectric elements 1820, and a second set of piezoelectric elements 1825. In some implementations, the first anchor 1805 (e.g., first constraint) and the second anchor 1810 (e.g., second constraint) are fixed elements of the magnetometer 1800. In some implementations, one or more of the piezoelectric elements 1825 includes a first metal layer 1830, a first piezoelectric element 1835, and a second metal layer 1840.

As shown in FIG. 18, the first metal layer 1830 is provided on a first surface (e.g., first Z-X surface plane) of the first piezoelectric element 1835. FIG. 18 also illustrates the second metal layer 1840 on a second surface (e.g., second Z-X surface plane) of the first piezoelectric element 1835. In some implementations, the first metal layer 1830 is a first electrode for the magnetometer. In some implementations, the second metal layer 1840 is a second electrode for the magnetometer. In some implementations, one or more (e.g., each) piezoelectric element of the magnetometer 1800 may include a first metal layer and a second metal layer that are configured to operate as an electrode. FIG. 18 illustrates the first and second metal layers 1830 & 1840 as having the similar dimensions as the first piezoelectric element 1835. However, in some implementations, the first and second metal layers 1830 & 1840 may have different dimensions from the first piezoelectric element 1835 (e.g., may be thinner, smaller, narrower, thicker). For example, the first and second metal layers 1830 & 1840 may only cover a portion of the surface area of the piezoelectric element 1835. The first set of piezoelectric elements 1820 may also include first and second metal layers. In some implementations, the magnetostrictive element 1815 may displace (e.g., move, bend) in response to a magnetic field. In some implementations, some portions of the piezoelectric layers 1820 and 1825 may displace (e.g., move, bend) when the magnetostrictive element 1815 is displaced.

FIG. 19 illustrates a magnetometer 1900 that includes a first anchor 1905, a second anchor 1910, a magnetostrictive element 1915 (e.g., magnetostrictive actuator), a first set of piezoelectric elements 1920, and a second set of piezoelectric elements 1925. In some implementations, the first anchor 1905 (e.g., first constraint) and the second anchor 1910 (e.g., second constraint) are fixed elements of the magnetometer 1900. In some implementations, the one or more of the piezoelectric elements 1925 includes a first metal layer 1930, a first piezoelectric element 1935, and a second metal layer 1940.

In some implementations, the one or more of the piezoelectric elements 1925 includes a first metal layer 1930, a first piezoelectric element 1935, and a second metal layer 1940.

FIG. 19 illustrates the first metal layer 1930 that is provided on a first surface (e.g., first Y-X surface plane) of the first piezoelectric element 1935. FIG. 19 also illustrates the second metal layer 1940 on a second surface (e.g., second Y-X surface plane) of the first piezoelectric element 1935. In some implementations, the first metal layer 1930 is a first electrode for the magnetometer. In some implementations, the second metal layer 1940 is a second electrode for the magnetometer. In some implementations, one or more (e.g., each) piezoelectric element of the magnetometer 1900 may include a first metal layer and a second metal layer that are configured to operate as an electrode. It should be noted that the shape and size of the first and second metal layers 1930 & 1940 may be different than what is illustrated in FIG. 19. For example, in some implementations, the first and second metal layers 1930 & 1940 may be the same size as the first piezoelectric element 1935. In some implementations, the first and second metal layers 1930 & 1940 may only cover a portion of the surface area of the piezoelectric element 1935. The first set of piezoelectric elements 1920 may also include first and second metal layers. In some implementations, the magnetostrictive element 1915 may displace (e.g., move, bend) in response to a magnetic field. In some implementations, some portions of the piezoelectric layers 1920 and 1925 may displace (e.g., move, bend) when the magnetostrictive element 1915 is displaced.

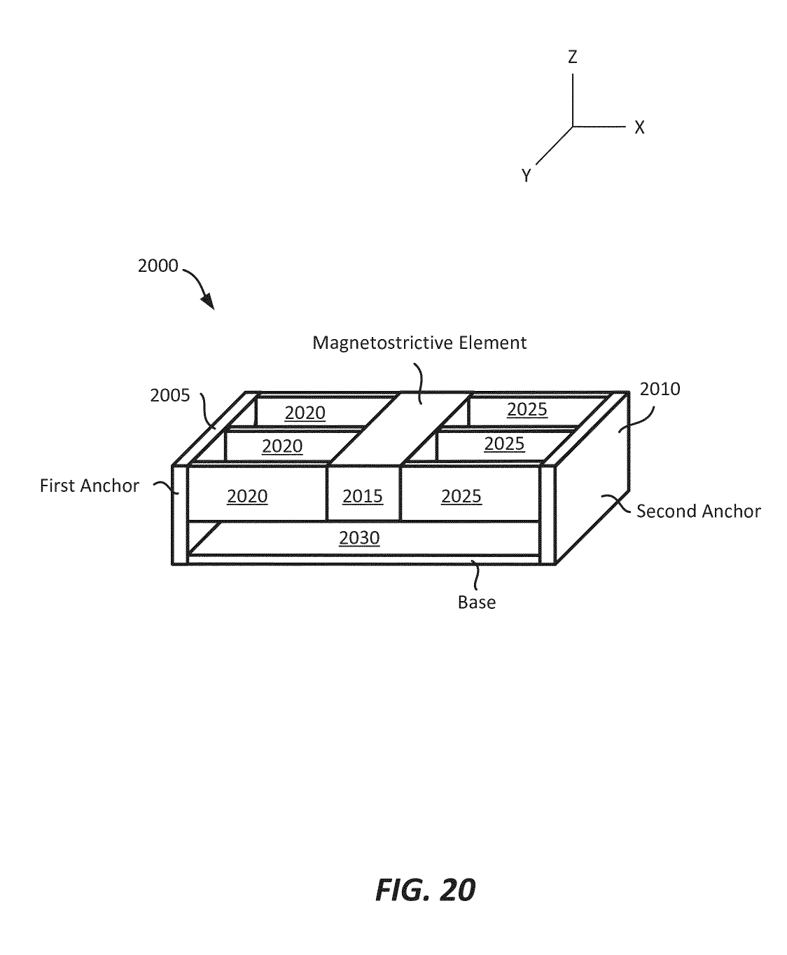

FIGS. 17-19 illustrate a magnetometer without a base. However, in some implementations, the magnetometer may include a base portion. FIG. 20 illustrates an example of a magnetometer that includes a base portion. Specifically, FIG. 20 illustrates a magnetometer 2000 that includes a first anchor 2005, a second anchor 2010, a magnetostrictive element 2015 (e.g., magnetostrictive actuator), a first set of piezoelectric elements 2020, a second set of piezoelectric elements 2025, and base 2030. In some implementations, the first anchor 2005 (e.g., first constraint), the second anchor 2010 (e.g., second constraint), and the base 2030 are fixed elements of the magnetometer 2000. In some implementations, the first anchor 2005, the second anchor 2010, and the base 2030 are a single element (e.g., one material). In some implementations, the magnetometer 2000 may be similar to the magnetometer described in FIGS. 17-19, except that the magnetometer of FIG. 20 includes a base portion. In some implementations, the magnetostrictive element 2015 may displace (e.g., move, bend) in response to a magnetic field. In some implementations, some portions of the piezoelectric layers 2020 and 2025 may displace (e.g., move, bend) when the magnetostrictive element 2015 is displaced.

In some implementations, the piezoelectric elements are thin film piezoelectric elements. In some implementations, a thin film piezoelectric element may have a thickness (e.g., height, dimension along Z-axis) of 500 microns (μm) or less. In some implementations, a thick film piezoelectric element may have a thickness (e.g., height, dimension along Z-axis) greater than 500 microns (μm) but less than 5 millimeters (mm).

Some implementations of the magnetoelectric magnetometer may include several magnetoelectric composites, where at least one of the magnetoelectric composites is aligned in a different direction than another magnetoelectric composite (e.g., a first magnetoelectric composite may be perpendicular and/or orthogonal to a second magnetoelectric composite). This configuration may allow the magnetoelectric magnetometer to measure and/or detect magnetic fields more accurately along different directions. Moreover, in some implementations, this configuration may allow for measurement of magnetic field direction in the x-y-z space or x-y plane or any other plane depending on whether using two or three perpendicular magnetometers.

Exemplary Method for Providing/Manufacturing a Magnetometer that Includes Stress Amplification

Different implementations may provide/manufacture the magnetometer described in the present disclosure in a different manner. In some implementations, a magnetometer may be provided/manufactured using Micro Electro Mechanical Systems (MEMS) fabrication methods. In some implementations, a magnetometer may be provided/manufactured using atomic layer deposition (ALD). In some implementations, a magnetometer may be provided/manufactured using chemical vapor deposition (CVD). In some implementations, a magnetometer may be provided/manufactured using a combination of ALD and CVD (e.g., hybrid ALD/CVD). That is, in some implementations, ALD may be used to provide/manufacture one or more components of the magnetometer (e.g., piezoelectric element), while CVD may be used to provide/manufacture one or more other components of the magnetometer.

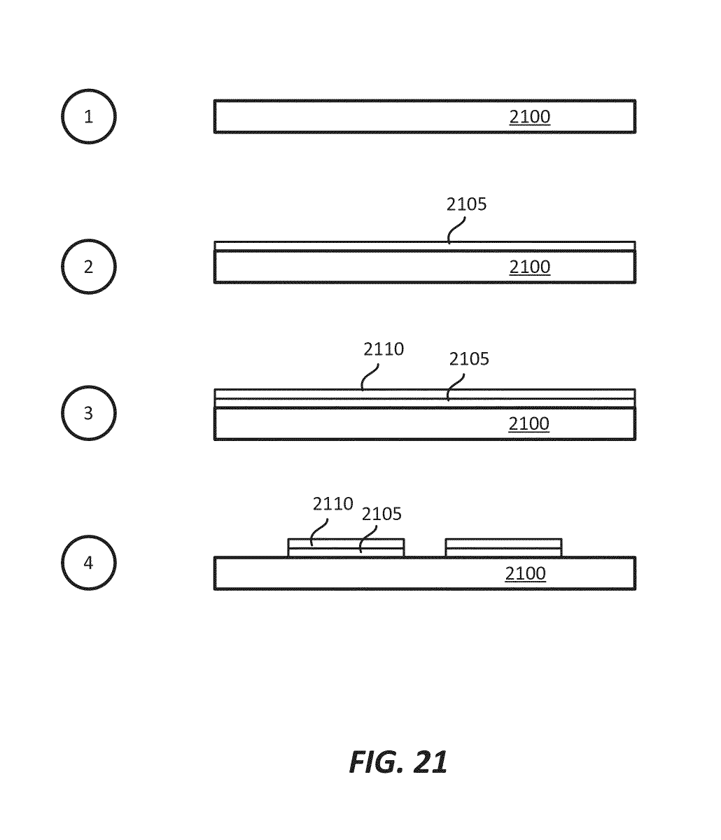

FIG. 21 illustrates an example of a sequence for providing/manufacturing one or more components of a magnetometer described in the present application. In some implementations, FIG. 21 illustrates a sequence that uses atomic layer deposition (ALD). In some implementations, FIG. 21 illustrates a sequence that uses chemical vapor deposition (CVD).

As shown in FIG. 21, a stage 1, a substrate 2100 is provided. The substrate 2100 may serve as a base and/or carrier on which one or more components of the magnetometer are provided. Different implementations may use different materials for the substrate 2100 (e.g., silicon, glass, ceramic).

At stage 2, a first piezoelectric layer 2105 is provided. In some implementations, the first piezoelectric layer 2105 is a thin film piezoelectric layer. In some implementations, the first piezoelectric layer 2105 is a piezoelectric seed layer. In some implementations, the first piezoelectric layer 2105 may be provided by ALD or CVD. When ALD is used, the first piezoelectric layer 2105 may be provided (1) providing a set of first precursor elements (e.g., precursor gas elements), (2) purging some of the first precursor elements, (3) providing a set of second precursor elements (e.g., precursor elements), and (4) purging some of the second precursor elements. In some implementations, when the set of second precursor elements is provided, the set of second precursor elements reacts with the first precursor elements to form the first piezoelectric layer 2105 on the substrate. It should be noted that in some implementations, more than two precursor elements may be provided.

When CVD is used, both the first and second precursors (e.g., first and second precursor gas elements) provided and react to form the first piezoelectric layer 2105. Thus, one difference between ALD and CVD is that ALD keeps the precursors separate during the coating of the substrate, whereas CVD does not.

At stage 3, a second piezoelectric layer 2110 is provided. In some implementations, the second piezoelectric layer 2110 is a thin film piezoelectric layer. In some implementations, the second piezoelectric layer 2110 may be provided by ALD or CVD. When ALD is used, the second piezoelectric layer 2110 may be provided by (1) providing a set of first precursor elements (e.g., precursor gas elements), (2) purging some of the first precursor elements, (3) providing a set of second precursor elements (e.g., precursor elements), and (4) purging some of the second precursor elements. In some implementations, when the set of second precursor elements is provided, the set of second precursor elements reacts with the first precursor elements to form the second piezoelectric layer 2110 on the substrate. It should be noted that in some implementations, more than two precursor elements may be provided.

When CVD is used, both the first and second precursors (e.g., first and second precursor gas elements) provided and react to form the second piezoelectric layer 2110.

In some implementations, stages 2 and/or 3 may be repeated several times until a desired height (e.g., thickness) is achieved. In some implementations, each stage may provide a piezoelectric layer that is between 0.1 and 3 angstrom (Å) thick.

At stage 4, some of the piezoelectric layers 2105 & 2110 are selectively removed. Different implementations may be used to selectively remove some of the piezoelectric layers 2105 & 2110. In addition, some implementations may remove some or all of the substrate 2100. In some implementations, remove some of the substrate 2100 beneath the piezoelectric layers would allow a portion (e.g., third portion) of the piezoelectric layers to move and/or bend, while other portions (e.g., first portion) of the piezoelectric layers to remain fixed (as they would be coupled and/or bonded to the substrate 2100). In some implementations, a laser may be used to etch away portions of the piezoelectric layers 2105 & 2110 and/or the substrate 2100. In some implementations, a mechanical means may be used to etch away portions of the piezoelectric layers 2105 & 2110. In some implementations, a chemical means may be used to etch away portions of the piezoelectric layers 2105 & 2110. In some implementations, the selective removing of the piezoelectric layers 2105 & 2110 may be optional.

After stage 4, other components of a magnetometer may be coupled to the piezoelectric layers 2105 & 2110. For example, constraints (e.g., anchor elements) may be coupled to the piezoelectric layers 2105 & 2110. In some implementations, the substrate 2100 is part of the constraints. Similarly, one or more magnetostrictive elements (e.g., magnetostrictive actuator) may be coupled to the piezoelectric layers 2105 & 2110. In some implementations, a separate thin film deposition process may be used to provide the magnetostrictive element. For example, stages 1-4 of FIG. 21 may be used using similar or different chemicals/precursor elements (e.g., precursor gases) in order to provide a magnetostrictive element. It should be noted that the process of providing the magnetostrictive element is not limited to ALD and/or CVD processes. Other thin film deposition processes may be used. It should also be noted that in some implementations, the constraints and/or magnetostrictive elements may be provided prior to providing the piezoelectric layers.

In some implementations, metal layers may also be coupled to the piezoelectric layers. In some implementations, these metal layers may be configured to operate as electrodes on the magnetometer. Different implementations may provide the metal layers differently. In some implementations, the metal layers are provided using an ALD and/or CVD process similar to the one described in FIG. 21. In some implementations, the metal layers may be provided using a plating process.

In some implementations, the magnetometer described in the present disclosure may be provided/manufactured using a macro scale process. In some implementations, a method provides a magnetoelectric composite by combining a magnetoelectric element (e.g., MetGlas) and the piezoelectric material (e.g., piezoelectric fiber composite such as PZT fiber). Different implementations may use different processes to combine the magnetoelectric element and the piezoelectric material. In some implementations, the fibers may be aligned at a certain angle (θ) to horizontal. The angle will be chosen for ease of manufacture while providing a nominal stress amplification factor.

### Exemplary Alternative Stress Amplification

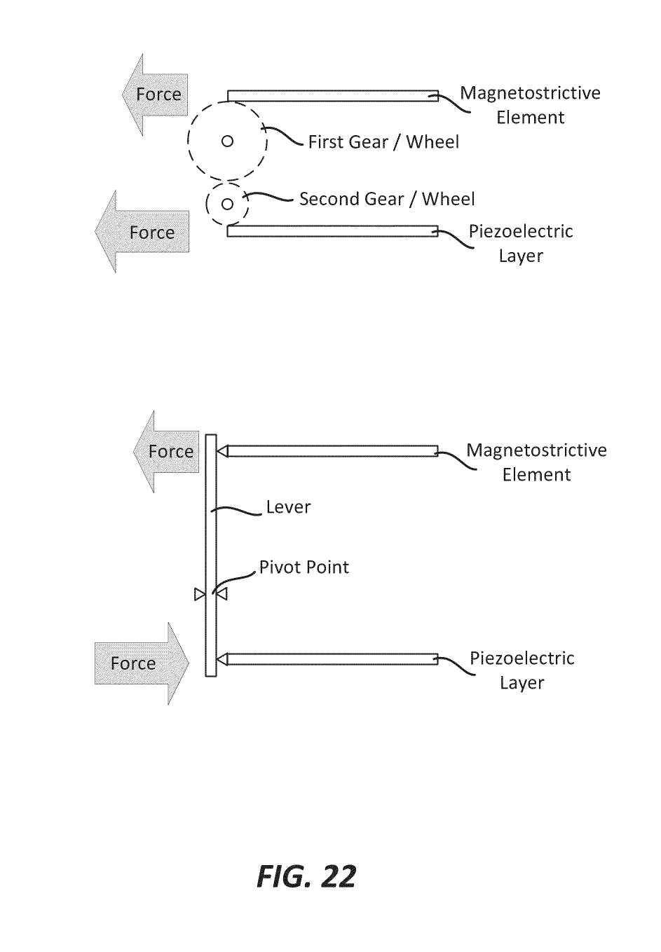

Stress amplification is one approach to utilizing mechanical advantage to increase the sensitivity of a magnetostrictive magnetometer. However, in some implementations, other types of mechanical advantage may be used to increase the sensitivity of the magnetostrictive magnetometer. For example, some implementations may use a pulley approach, a lever approach, a fluid approach, a friction approach (e.g., using high friction wheels) and/or gear approach to provide increase sensitivity. Such examples are illustrated in FIG. 22. Different implementations will result in different mechanical advantages. Some implementations may provide a mechanical advantage amplification that ranges from 2:1 to 100:1.

### Exemplary Applications of Magnetoelectric Magnetometer

The above described magnetoelectric magnetometers may be used in a variety of applications. For example, the above magnetometers may be used as compasses in phones (e.g., smart phones), tablets and/or global positioning system (GPS) devices to provide compassing and/or directional functions. In addition, the above described magnetometers may be used in magnetocardiography to measure heart rate. In some implementations, the magnetoelectric magnetometers may also be used in magnetoencephalography to provide brain imaging of neuronal activity. Moreover, in some implementations, the magnetoelectric magnetometers may be used in radio frequency identification (RFID) devices and/or near field communication (NFC) devices. In such instances, the magnetoelectric magnetometers may be configured to operate as a transmitter and/or received for the NFC. That is the magnetoelectric magnetometers may replace the functionality of a coil and/or inductor in an NFC device.

One or more of the elements, steps, features, and/or functions illustrated in FIGS. 1, 2, 3, 4, 5, 6, 7, 8, 9, 10, 11, 12, 13, 14, 15, 16, 17, 18, 19, 20, 21 and/or 22 may be rearranged and/or combined into a single component, step, feature or function or embodied in several components, steps, or functions. Additional elements, components, steps, and/or functions may also be added without departing from the invention.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other.

In the present disclosure, the magnetostrictive element are shown has having a beam configuration (e.g., where one dimension of the magnetostrictive element is substantially greater than the other dimensions of the magnetostrictive element). For example, in a beam configuration the length (e.g., first dimension) of the magnetostrictive element is substantially greater than either the width (e.g., second dimension) or height (e.g., third dimension) of the magnetostrictive element. In some implementations, the length of a magnetostrictive element may be at least 2 times greater than the width and/or the height of the magnetostrictive element. However, it should be noted that in some implementations, other sizes and shapes of the magnetostrictive element may be used in the present disclosure. In addition, in some implementations, more than one magnetostrictive element may be used in a magnetometer.

Some or all of the magnetostrictive magnetometers may include one or more metal layers, even if such metal layers are not shown in the figures. These one or more metal layers may be positioned on any surface of the piezoelectric element and/or layer (e.g., electrical active element and/or layer) described in the present disclosure. In some implementations, the generated/induced electric field (e.g., current and/or voltage) may be measured on or between these metal layers.

It should also be noted that the piezoelectric layer described in the present disclosure may be any electric active element that exhibits electrical polarization when subjected to a mechanical stress, and/or that builds up an electrical charge when subjected to a mechanical stress.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A magnetometer comprising:
an electrical active layer comprising a first end portion, a second end portion, and a third portion, the third portion located between the first end portion and the second end portion; and
a magnetostrictive element coupled to the third portion of the electrical active layer, wherein the magnetostrictive element and the electrical active layer are configured to amplify a magnetically induced stress in the magnetostrictive element to the electrical active layer, resulting in an electrical response from the electrical active layer.

2. The magnetometer, wherein the electrical active layer is a piezoelectric layer that exhibits an electrical polarization when subjected to a mechanical stress.

3. The magnetometer of claim 1, wherein the first and second end portions of the electrical active layer are fixed, while the third portion is free to bend.

4. The magnetometer of claim 1 further comprising a constraint layer coupled to the electrical active layer.

5. The magnetometer of claim 4, wherein the constraint layer comprises a first constraint end portion and a second constraint end portion, the first constraint end portion being coupled to the first end portion of the electrical active layer, the second constraint end portion being coupled to the second end portion of the electrical active layer.

6. The magnetometer of claim 1 further comprising at least one metal layer coupled to the electrical active layer.

7. The magnetometer of claim 1, wherein the electrical active layer has a first stiffness that is similar to the second stiffness of the magnetostrictive element.

8. The magnetometer of claim 7, wherein the constraint layer has a third stiffness that is substantially higher than the first stiffness.

9. The magnetometer of claim 1, wherein the electrical active layer is a thin film layer having a thickness of 500 microns (μm) or less.

10. The magnetometer of claim 1, wherein the electrical active layer is a thick film layer having a thickness of more than 500 microns (μm) and less than 5 millimeters (mm).

11. The magnetometer of claim 1 further comprising at least one metal layer configured to allow a measurement of the electrical response.

12. The magnetometer of claim 1, wherein the electric active layer has a surface area to volume ratio of at least 2:1.

13. The magnetometer of claim 1, wherein the magnetostrictive element and the electrical active layer are configured to amplify the magnetically induced stress in the magnetostrictive element to the electrical active layer by an amplification factor that is greater than one.

14. The magnetometer of claim 13, wherein the amplification factor is defined by 1/(2 tan θ).

15. The magnetometer of claim 1, wherein the magnetostrictive element has a beam configuration.

16. A magnetoelectric magnetometer comprising:
one or more electrical active layers;
one or more magnetostrictive layers; and
wherein the magnetostrictive layer and electrical active layer are mechanically coupled via a mechanism for amplifying the magnetically induced stress in the magnetostrictive layer by the location of said mechanical coupling and the geometry of the electrical active layer.

17. The magnetometer of claim 16, wherein said electrical active layers have opposite ends, wherein the first and second ends of the electrical active layer are clamped, the electrical active layer having a center region between said ends, wherein the magnetostrictive layer is bonded, the electrical active layers being polarized along the width between said ends, wherein the stress induced by the magnetic field applied along the length of the magnetostrictive layer and applied on the electrical active layer is amplified.

18. The magnetometer of claim 17, wherein the magnetometer comprises two magnetostrictive layers one magnetostrictive layer is bonded on top of electrical active layer and second magnetostrictive layer is bonded directly underneath electrical active layer.

19. The magnetometer of claim 17, wherein region of the electrical active layer not attached to magnetostrictive layer are tilted at a certain angle from horizontal.

20. The magnetometer of claim 19, wherein said angle is from ±20°.

21. The magnetometer of claim 17, wherein said electrical active layers are individually comprised of two separate electrical active layers, the electrical active layers having opposite ends, wherein the first end of first electrical active layer and second end of second electrical active layer are clamped, and the second end of first electrical active layer and the first end of second electrical active layer are mechanically attached to a magnetostrictive layer.

22. The magnetometer of claim 16, wherein said electrical active layers have opposite ends, wherein the first and second ends of the electrical active layer are clamped, the electrical active layer having a center region between said ends, wherein the magnetostrictive layer is bonded, the electrical active layers being polarized along the thickness of the electrical active layers, wherein the stress induced by the magnetic field applied along the length of the magnetostrictive layer and applied on the electrical active layer is amplified.

23. The magnetometer of claim 16, wherein the mechanism for amplifying provides a mechanical advantage amplification that ranges from 2:1 to 100:1.

24. The magnetometer of claim 16, wherein the electrical active layer comprises of a monolithic electrical active layer.

25. The magnetometer of claim 16, wherein the electrical active layer comprises of a piezoelectric fiber composite.

26. The magnetometer of claim 16, wherein the electrical active layer comprises of at least one material selected from: a piezoelectric polymer, a piezoelectric ceramic, a piezoelectric single crystal and aluminum nitride.

27. The magnetometer of claim 16, wherein the magnetostrictive layer comprises of at least one material selected from: Terfenol-D, Galfenol, and Metglas.

28. An apparatus comprising:
an electrical active means configured to provide an electrical response when subject to a mechanical stress; and
a magnetostrictive means coupled to the electrical active means, wherein the magnetostrictive means and the electrical active means are configured to amplify a magnetically induced stress in the magnetostrictive means to the electrical active means, resulting in an electrical response from the electrical active means.

29. The apparatus of claim 14, wherein the electrical active means is a piezoelectric layer.

30. A method for providing a magnetoelectric magnetometer, comprising:
providing an electrical active layer comprising a first end portion, a second end portion, and a third portion, the third portion located between the first end portion and the second end portion; and
providing a magnetostrictive element coupled to the third portion of the electrical active layer, wherein the magnetostrictive element and the electrical active layer are configured to amplify a magnetically induced stress in the magnetostrictive element to the electrical active layer, resulting in an electrical response from the electrical active layer.
